(19) United States
(12) Patent Application Publication
(10) Pub. No.: US 2026/0352169 A1
(43) Pub. Date: Nov. 5, 2026

(54) CONTROL CIRCUIT FOR CLASS AB OUTPUT STAGE

(71) Applicant: TEXAS INSTRUMENTS INCORPORATED, Dallas, TX (US)

(72) Inventors: Purnendu Bhattaru, Bangalore (IN); Tyler James Archer, Vail, AZ (US); Bharath Karthik Vasan, Tucson, AZ (US)

(21) Appl. No.: 19/345,404

(22) Filed: Sep. 30, 2025

Related U.S. Application Data
(60) Provisional application No. 63/797,279, filed on Apr. 30, 2025.

(51) Int. Cl. H03F 3/21

(52) U.S. Cl. CPC H03F 3/21; H03F 2200/129

(57) ABSTRACT

An electronic circuit includes a first supply terminal, a second supply terminal, first and second input terminals, an output terminal, a first transistor, a second transistor, a first voltage buffer having an input coupled to the first input terminal, and an output coupled to the first transistor, a first capacitor coupled between an input and the output of the first voltage buffer, a second voltage buffer having an input coupled to the second input terminal, and an output terminal coupled to the second transistor, a second capacitor coupled between the input and the output of the second voltage buffer, a third capacitor coupled between the input of the first voltage buffer and the output terminal, a fourth capacitor coupled between the input of the second voltage buffer and the output terminal, and a bias circuit configured to provide a first bias current and a second bias current.

### RELATED APPLICATION

This application claims priority to U.S. Provisional Application No. 63/797,279, filed Apr. 30, 2025, entitled “Method for Driving Output Transistor Bases in Class AB Monticelli Output Stages in Bipolar Amplifiers,” which is hereby incorporated by reference.

### TECHNICAL FIELD

The present disclosure relates generally to an electronic system and method, and, in particular embodiments, to a control circuit for a class AB output stage.

### BACKGROUND

A Monticelli output stage in a bipolar amplifier, particularly in a class AB configuration, utilizes a pair of output transistors (one NPN transistor and one PNP transistor) to drive the output load.

### SUMMARY

In accordance to an embodiment, an electronic circuit includes: a first supply terminal; a second supply terminal; first and second input terminals configured to receive an input signal; an output terminal configured to provide an output signal based on the input signal; a first transistor having a first current path terminal coupled to the first supply terminal, a second current path terminal coupled to the output terminal, and a control terminal; a second transistor having a first current path terminal coupled to the output terminal, a second current path terminal coupled to the second supply terminal, and a control terminal; a first voltage buffer having an input coupled to the first input terminal, and an output coupled to the control terminal of the first transistor; a first capacitor coupled between an input of the first voltage buffer and the output of the first voltage buffer; a second voltage buffer having an input coupled to the second input terminal, and an output terminal coupled to the control terminal of the second transistor; a second capacitor coupled between the input of the second voltage buffer and the output of the second voltage buffer; a third capacitor coupled between the input of the first voltage buffer and the output terminal; a fourth capacitor coupled between the input of the second voltage buffer and the output terminal; and a bias circuit configured to provide a first bias current to the first input terminal, and a second bias current to the second input terminal.

In accordance to an embodiment, an electronic circuit includes: a first supply terminal; a second supply terminal; first and second input terminals each configured to receive an input signal; an output terminal configured to provide an output signal based on the input signal; a first transistor having a first current path terminal coupled to the first supply terminal, a second current path terminal coupled to the output terminal, and a control terminal; a second transistor having a first current path terminal coupled to the output terminal, a second current path terminal coupled to the second supply terminal, and a control terminal; a first voltage buffer includes: a third transistor having a control terminal coupled to the first input terminal; and a fourth transistor having a first current path terminal coupled to the control terminal of the first transistor, and a control terminal coupled to a second current path terminal of the third transistor; a second voltage buffer includes: a fifth transistor having a control terminal coupled to the second input terminal; and a sixth transistor having a current path terminal coupled to the control terminal of the second transistor, and a control terminal coupled to a first current path terminal of the fifth transistor; a first capacitor coupled between the first input terminal and the control terminal of the first transistor; a second capacitor coupled between the second input terminal and the control terminal of the second transistor; a third capacitor coupled between the first input terminal and the output terminal; a fourth capacitor coupled between the second input terminal and the output terminal.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 depicts a schematic diagram of an example of an electronic circuit for driving output transistors of an amplifier, in accordance with an embodiment of the present disclosure;

FIG. 2 depicts an example of a schematic diagram illustrating impact of the feedforward capacitors on Miller loop stability of the electronic circuit, in accordance with an embodiment of the present disclosure;

FIGS. 3A and 3B (collectively, FIG. 3) depicts a schematic diagram of an example of a two-rank implementation of the first zero-offset voltage buffer and the second zero-offset voltage buffer in FIG. 1, in accordance with an embodiment of the present disclosure;

FIGS. 4A and 4B (collectively, FIG. 4) depict a schematic diagram of an example of a two-rank implementation where the additional voltage offset cancellation transistors are implemented within the zero-offset voltage buffers instead of within the bias circuit, in accordance with an embodiment of the present disclosure;

FIG. 5A depicts a schematic diagram of an example of an implementation of the zero-offset voltage buffers of FIG. 4 with additional drive-boosting current loops, in accordance with an embodiment of the present disclosure; and

FIG. 5B depicts a schematic diagram of an example of another implementation of the zero-offset voltage buffers of FIG. 4 with additional drive-boosting current loops, in accordance with an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be obtained without one or more of the specific details, or with other methods, components, materials and the like. In some cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

The output transistors in the class AB Monticelli output stages of bipolar amplifiers may have non-linear, signal-dependent base currents that have to be provided by the previous/input stage. These non-linear, signal-dependent base currents may degrade linearity, DC precision, and output drive performance of the bipolar amplifier significantly in the case of a two-stage implementation, making it very difficult for the bipolar amplifier to operate at high speed.

Some embodiments utilize two zero-offset voltage buffers/drivers with feedforward capacitors to drive the bases of the output transistors of an output stage of a bipolar amplifier while presenting a high input impedance to the previous (e.g., input) stage of the bipolar amplifier with zero base driver offset voltage, enabling operations on lower supply voltages. Such approach may advantageously enable high linearity, DC precision, output drive, bandwidth, and slew rate of the bipolar to be achieved while producing small supply current spikes when the bipolar amplifier's output saturates. The approach may also advantageously enable operations on low supply voltages and may deliver superior output overdrive supply-current behavior. As discussed below, the feedforward capacitors may advantageously reduce base driver forward signal phase loss, enabling high amplifier stability margins to be achieved.

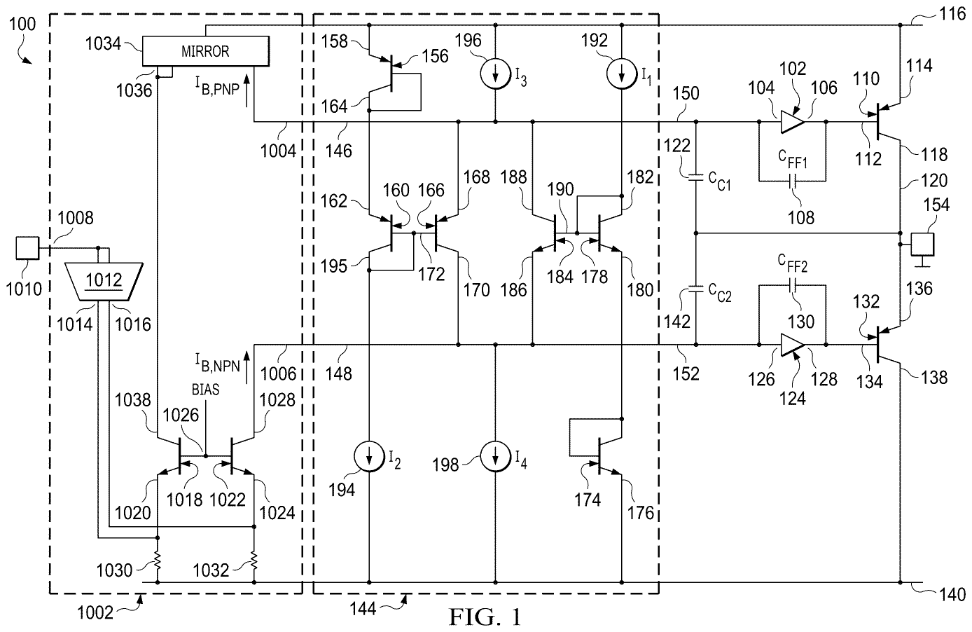

FIG. 1 depicts a schematic diagram of an example of an electronic circuit 100 for driving output transistors of an amplifier. As shown in FIG. 1, the electronic circuit 100 includes a first zero-offset voltage buffer 102 having an input terminal (a first current terminal) 104 and an output terminal (a second current terminal) 106, where the first zero-offset voltage buffer 102 introduces zero voltage offset between the input terminal 104 and the output terminal 106. A first feedforward capacitor C_{FF1} 108 is coupled between the input terminal 104 and the output terminal 106 of the first zero-offset voltage buffer 102. A first output (e.g., the first PNP bipolar) transistor 110 has a base 112 coupled to and driven by the output terminal 106 of the first zero-offset voltage buffer 102. The first output transistor 110 also has an emitter 114 coupled to a first supply terminal 116 and a collector 118 coupled to an output terminal 120 of the electronic circuit 100. In one example, a first compensation capacitor C_{C1} 122 is coupled between the input terminal 104 of the first zero-offset voltage buffer 102 and the output terminal 120 of the electronic circuit 100. The electronic circuit 100 also includes a second zero-offset voltage buffer 124 having an input terminal (a first current terminal) 126 and an output terminal (a second current terminal) 128. A second feedforward capacitor C_{FF2} 130 is coupled between the input terminal 126 and the output terminal 128 of the second zero-offset voltage buffer 124. A second output (e.g., the first NPN bipolar) transistor 132 has a base 134 coupled to and driven by the output terminal 128 of the second zero-offset voltage buffer 124. The second output transistor 132 also has a collector 136 coupled to the output terminal 120 of the electronic circuit 100 and an emitter 138 coupled to a second supply terminal 140. In one example, a second compensation capacitor C_{C2} 142 is coupled between the input terminal 126 of the second zero-offset voltage buffer 124 and output terminal 120 of the electronic circuit 100. In one example, the first and the second compensation capacitors C_{C1} 122 and C_{C2} 142 are the same.

In one example, a first supply voltage AVCC at the first supply terminal 116 is higher than a second supply voltage AVEE at the second supply terminal 140. In one example, the first supply voltage AVCC and/or the second supply voltage AVEE is provided by one or more coin-cell batteries. In one example, the output terminal 120 of the electronic circuit 100 couples to an external electronic device 154, where the external electronic device can be but is not limited to a resistor, a power amplifier, an analog to a digital converter (ADC), etc.

In one example, the electronic circuit 100 further includes a bias circuit 144 having a first current terminal 146 configurable to receive a first current I_{B,PNP} for the first zero-offset voltage buffer 102, the a second current terminal 148 configurable to receive a second current I_{NPN} for the second zero-offset voltage buffer 124, a third current terminal 150 coupled to the first current terminal 146 and the input terminal 104 of the first zero-effect voltage buffer 102, and a fourth current terminal 152 coupled to the second current terminal 148 and the input terminal 126 of the second zero-effect voltage buffer 124. As shown in FIG. 1, the bias circuit 144 includes a second PNP transistor 156 having an emitter 158 coupled to the first supply terminal 116, where the second PNP transistor 156 is diode-connected. The bias circuit 144 further includes a first current mirror having a third PNP transistor 160 and a fourth PNP transistor 166. The third PNP transistor 160 has an emitter 162 coupled to a collector 164 of the second PNP transistor 156, where the third PNP transistor 160 is diode-connected. The fourth PNP transistor 166 has an emitter 168 coupled to the third current terminal 150, a collector 170 coupled to the fourth current terminal 152, and a base 172 coupled to a base of the third PNP transistor 160. In one example, the bias circuit 144 further includes a second NPN transistor 174 having an emitter 176 coupled to the second supply terminal 140, where the second NPN transistor 174 is diode-connected. The bias circuit 144 further includes a second current mirror having a third NPN transistor 178 and a fourth NPN transistor 184. The third NPN transistor 178 has an emitter 180 coupled to a collector 182 of the second NPN transistor, where the third NPN transistor 178 is diode-connected. The fourth NPN transistor 184 has an emitter 186 coupled to the fourth current terminal 152, a collector 188 coupled to the third current terminal 150, and a base 190 coupled to a base of the third NPN transistor 178. In one example, the bias circuit 144 further includes a first bias current source 192 coupled between the first supply terminal 116 and the collector 182 of the third NPN transistor 178. The bias circuit 144 further includes a second bias current source 194 coupled between a collector 195 of the third PNP transistor 160 and the second supply terminal 140. The bias circuit 144 further includes a third bias current source 196 coupled between the first supply terminal 116 and the third current terminal 150 and a fourth current source 198 coupled between the fourth current terminal 152 and the second supply terminal 140.

In one example, the electronic circuit 100 further includes an input stage 1002 configurable to provide the first current I_{B,PNP} and the second current I_{B,NPN} to the bias circuit 144, where input stage 1002 has a first current terminal 1004 coupled to the first current terminal 146 of the bias circuit 144, a second current terminal 1006 coupled to the second current terminal 148 of the bias circuit 144, and one or more voltage input terminals 1008 coupled to an external electronic device 1010. In one example, the external electronic device 1010 is a sensing device such as a sonar or includes an antenna coupled to the external electronic device 1010.

As shown in FIG. 1, in one example, the input stage 1002 includes a transconductance amplifier 1012 configurable to receive inputs from the one or more voltage input terminals 1008 and to provide multiple (e.g., two) output voltage signals at a first output terminal 1014 and a second output terminal 1016, respectively. In one example, the input stage 1002 further includes a NPN transistor 1018 having an emitter 1020 coupled to the first output terminal 1014 of the transconductance amplifier 1012 and a NPN transistor 1022 having an emitter 1024 coupled to the second output terminal 1016 of the transconductance amplifier 1012, a base 1026 coupled to a base of the NPN transistor 1018, and a collector 1028 coupled to the second current terminal 148 of the bias circuit 144. In one example, the base 1026 is configurable to receive a bias signal to both the NPN transistor 1018 and the NPN transistor 1022. In one example, the input stage 1002 further includes a first resistor 1030 coupled between the emitter 1020 of the NPN transistor 1018 and the second supply terminal 140, and a second resistor 1032 coupled between the emitter 1024 of the NPN transistor 1022 and the second supply terminal 140. In one example, the input stage 1002 further includes a current mirror 1034 configurable to receive the first current I_{PNP} from the first current terminal 1004 and provide a mirrored current to a collector 1038 of the NPN transistor 1018 via an output terminal 1036.

In the example of FIG. 1, the zero-offset voltage buffers 102 and 14 preserves headroom, enabling operation with supplies down to, e.g., 2.7V. The feedforward capacitors C_{FF1} 108 and C_{FF2} 130 minimize high-frequency phase loss across output base drivers, enabling high bandwidth and slew rate while maintaining stability.

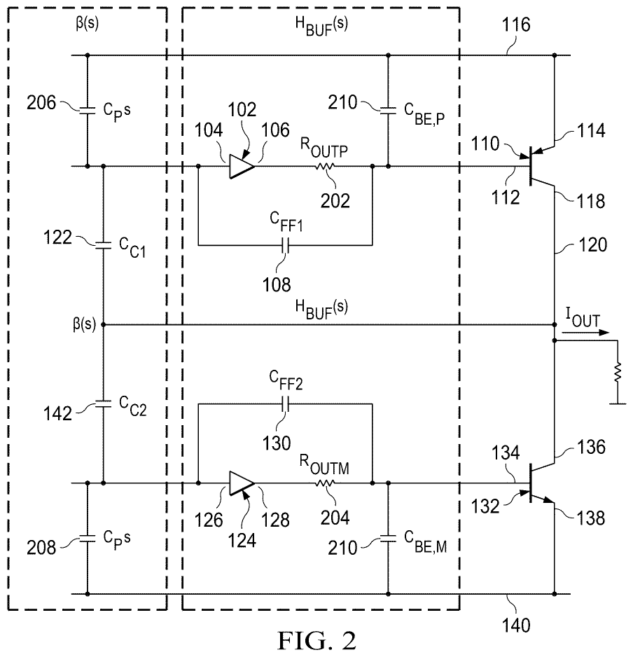

FIG. 2 depicts an example of a schematic diagram illustrating impact of the feedforward capacitors on Miller loop stability of the electronic circuit 100. As shown in FIG. 2, the first zero-offset voltage buffer 102 and the second zero-offset voltage buffer 124 introduces buffer output impedance R_{OUTP} 202 and R_{OUTM} 204 at the output terminals 106 and 128, respectively. The feedback loops may introduce parasitic capacitances Cₚs 206/208 between the input terminals 102 and 126 and the first and the second supply terminals 116 and 140, respectively, e.g., mostly due to connection of the multiple devices, where such capacitances may cause instability issue for the feedback loop. The output transistors 110 and 132 also have base-emitter capacitances C_{BE,P} 210 and C_{BE,M} 212 between the bases (112, 134) and the emitters (114, 138) of the output transistors 102 and 126, respectively. During operation, C_{BE,P} 210 and C_{BE,M} 212 increase as output current I_{OUT} increases on both the sourcing and sinking sides. The buffer transfer function H_{BUF}(s) drops as I_{OUT} increases, causing feedback factor β(s) to drop as well due to increase in phase lag from RC at the output terminals of the buffers. By forming a capacitive divider with C_{BE,P} 210 and C_{BE,M} 212, the feedforward capacitors C_{FF1} 108 and C_{FF2} 130 create additional zero(s) in the buffer transfer function H_{BUF}(s), resulting in a phase boost that compensates for/limits the buffer phase lag thus improving phase margin. In one example, magnitude of H_{BUF}(s) drops close to zero around Miller loop unity-gain bandwidth (UGB), where drops in β(s) reduces the UGB, further improving the phase margin.

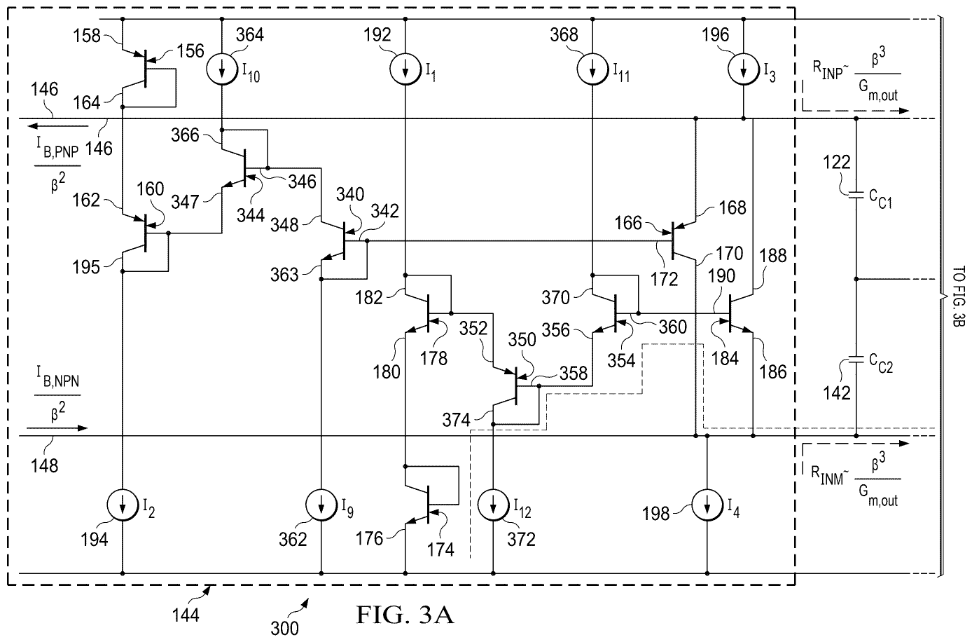

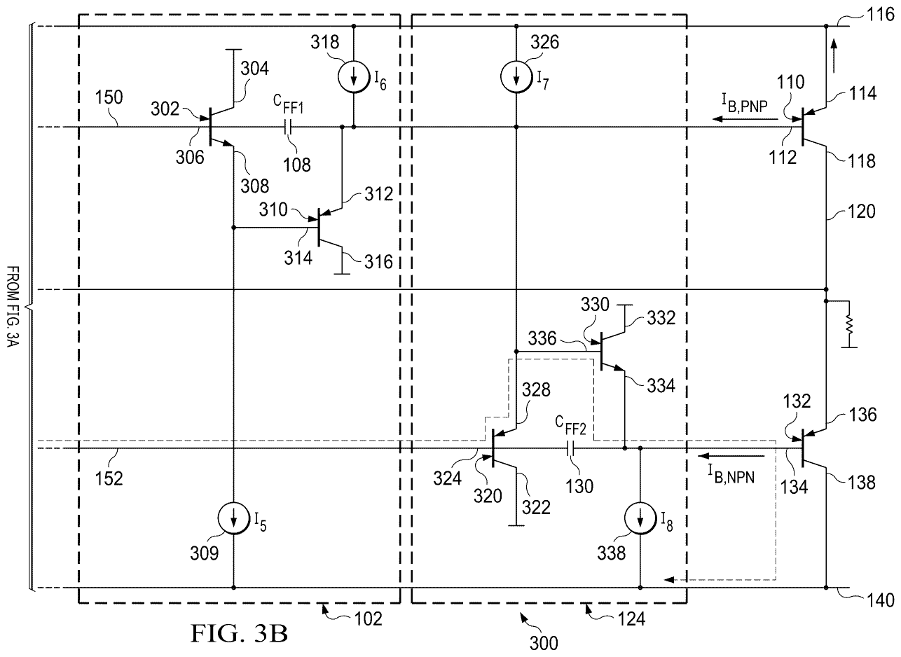

FIG. 3 depicts a schematic diagram of an example of a two-rank implementation of the first zero-offset voltage buffer 102 and the second zero-offset voltage buffer 124 in FIG. 1. In one example, the first zero-offset voltage buffer 102 includes a first rank comprising a fifth NPN transistor 302 having a collector 304 coupled to the first supply terminal 116 and a base 306 coupled to the first current terminal 104 of the first zero-effect voltage buffer 102. The first rank of the first zero-offset voltage buffer 102 further includes a fifth bias current source 309 coupled between an emitter 308 of the fifth NPN transistor 302 and the second supply terminal 140. The first zero-offset voltage buffer 102 further includes a second rank comprising a fifth PNP transistor 310 having an emitter 312 coupled to the second current terminal 106 of the first zero-effect voltage buffer 102, a base 314 coupled to the emitter 308 of the fifth NPN transistor 302, and a collector 316 coupled to the second supply terminal 140. The second rank of the first zero-offset voltage buffer 102 further includes a sixth bias current source 318 coupled between the first supply terminal 116 and the second current terminal 106 of the first zero-effect voltage buffer 102.

As shown in FIG. 3, in one example, the second zero-offset voltage buffer 124 includes a first rank comprising a six PNP transistor 320 having a collector 322 coupled to the second supply terminal 140 and a base 324 coupled to the first current terminal 126 of the second zero-offset voltage buffer 124. The first rank of the second zero-offset voltage buffer 124 further includes a seventh bias current source 326 coupled between the first supply terminal 116 and an emitter 328 of the six PNP transistor 320. The second zero-offset voltage buffer 124 further includes a second rank comprising a six NPN transistor 330 having a collector 332 coupled to the first supply terminal 116, an emitter 334 coupled to the second current terminal 128 of the second zero-effect voltage buffer 124, and a base 336 coupled to the emitter 328 of the six PNP transistor 320. The second rank of the second zero-offset voltage buffer 124 further includes an eighth bias current source 338 coupled between the second current terminal 128 of the second zero-effect voltage buffer 124 and the second supply terminal 140.

The two-rank implementation of the first zero-offset voltage buffer 102 and second zero-offset voltage buffer 124 described above drives the bases (112 and 134) of the output transistors 110 and 132, respectively, while attenuating the base currents I_{B,PNP} and I_{B,NPN} from the first output transistor 110 and the second output transistor 132, respectively, by two stages of current gain (β²) and presenting a high input impedance to the previous (input) stage 1002. Since the buffers are implemented without diode-connected transistors, they thereby reduce their headroom requirements and achieve the minimum supply voltage, e.g., 2V (voltage of the seventh bias current source 326 +V_{BE} of the six NPN transistor 330+V_{BE} of second output transistor 132). In one example, additional voltage offset cancellation transistors (e.g., diode-connected transistors) can be utilized to cancel any residual offset voltages due to the VBE differences of the PNP and NPN transistors and to prevent any impact to output transistor biasing. Specifically, in one example, the bias circuit 144 further includes a seventh PNP transistor 340 having a base 342 coupled to the base 172 of the fourth PNP transistor 166 to adjust its base voltage biasing, where the seventh PNP transistor 340 is diode-connected. The bias circuit 144 further includes a seventh NPN transistor 344 having a base 346 coupled to an emitter 348 of the seventh PNP transistor 340 and an emitter 347 coupled to the control terminal of the third PNP transistor 160, where the seventh NPN transistor 344 is diode-connected. In one example, the bias circuit 144 further includes an eighth PNP transistor 350 having an emitter 352 coupled to the base 190 of the third NPN transistor 178, where the eighth PNP transistor 350 is diode-connected. The bias circuit 144 further includes an eighth NPN transistor 354 having an emitter 356 coupled to a base 358 of the eighth PNP transistor 358, and a base 360 coupled to the base 190 of the fourth NPN transistor 184 to adjust its base voltage biasing, where the eighth NPN transistor 354 is diode-connected.

To provide bias currents to these diode-connected transistors, in one example, the bias circuit 144 further includes a ninth bias current source 362 coupled between a collector 363 of the seventh PNP transistor 340 and the second supply terminal 140. The bias circuit 144 further includes a tenth bias current source 364 coupled between the first supply terminal 116 and a collector 366 of the seventh NPN transistor 344. The bias circuit 144 further includes an eleventh bias current source 368 coupled between the first supply terminal 116 and a collector 370 of the eighth NPN transistor 354. The bias circuit 144 further includes a twelfth current source 372 coupled between a collector 374 of eighth PNP transistor 350 and the second supply terminal 140.

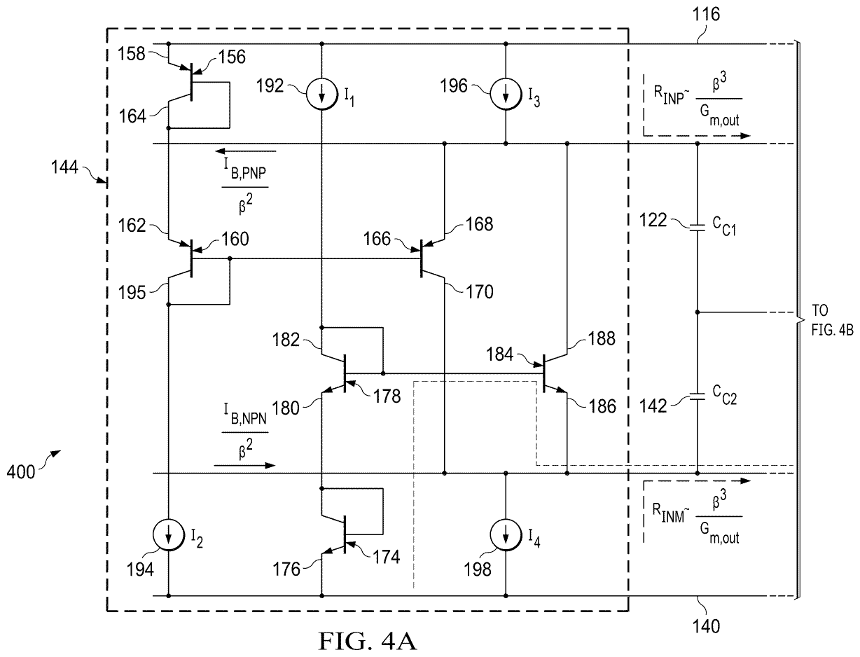

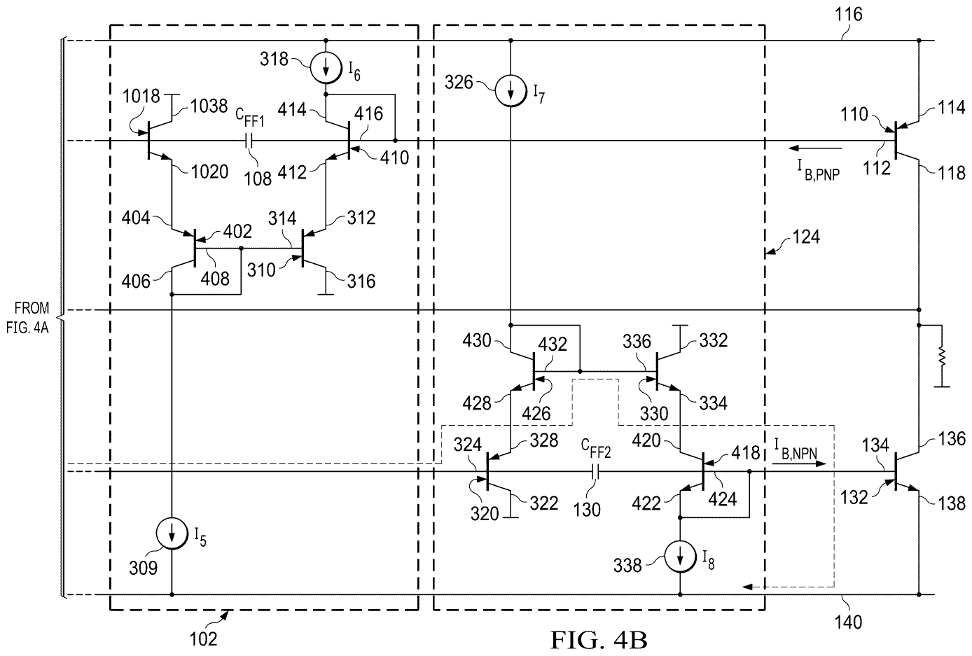

The approach of two-rank implementation of the zero-offset voltage buffers together with the voltage offset cancellation transistors and their associated bias current sources reduces input stage loading and delivers superior open-loop gain and distortion performance. The approach also delivers higher bandwidth and slew rate with a short signal path, enabling high-speed operation without large-signal distortion. collectively, FIG. 4 depicts a schematic diagram of an example of a two-rank implementation 400 where the additional voltage offset cancellation transistors are implemented within the first zero-offset voltage buffer 102 and the second zero-offset voltage buffer 124 instead of within the bias circuit 144. As shown in FIG. 4, in one example, the first rank of the first zero-offset voltage buffer 102 further includes a ninth PNP transistor 402 having an emitter 404 coupled to the emitter 308 of the fifth NPN transistor 302, a collector 406 coupled to the first bias current source 309, and a base 408 coupled to the base 314 of the fifth PNP transistor 310, where the ninth PNP transistor 402 is diode-connected. In one example, the second rank of the first zero-offset voltage buffer 102 further includes a ninth NPN transistor 410 having an emitter 412 coupled to the emitter 312 of the fifth PNP transistor 310, a collector 414 coupled to the sixth bias current source 318, and a base 416 coupled to the second current terminal 106 of the first zero-offset voltage buffer 102, where the ninth NPN transistor 410 is diode-connected. In one example, the first rank of the second zero-offset voltage buffer 124 further includes a tenth NPN transistor 426 having an emitter 428 coupled to the emitter 328 of the sixth PNP transistor 320, a collector 430 coupled to the seventh bias current source 326, and a base 432 coupled to the base 336 of the sixth NPN transistor 330, where the tenth NPN transistor 426 is diode-connected. In one example, the second rank of the second zero-offset voltage buffer 124 further includes a tenth PNP transistor 418 having an emitter 420 coupled to the emitter 334 of the sixth NPN transistor 330, a collector 422 coupled to the eighth bias current source 338, and a base 424 coupled to the second current terminal 128 of the second zero-offset voltage buffer 124, where the tenth PNP transistor is diode-connected.

By implementing the voltage offset cancellation transistors within the zero-offset voltage buffers instead of the bias circuit 144, the implementation as shown in FIG. 4 saves four bias current sources (362, 364, 368, and 372) compared to the implementation as shown in FIG. 3. Compared to the implementation 300 of FIG. 3, the minimum supply voltage of the implementation 400 of FIG. 4 can be a bit higher, e.g., 2.7V (voltage of the seventh bias current source 326+V_{BE} of the six NPN transistor 330+V_{BE} of the tenth PNP transistor 418+V_{BE} of second output transistor 132) without high-frequency large-signal distortion.

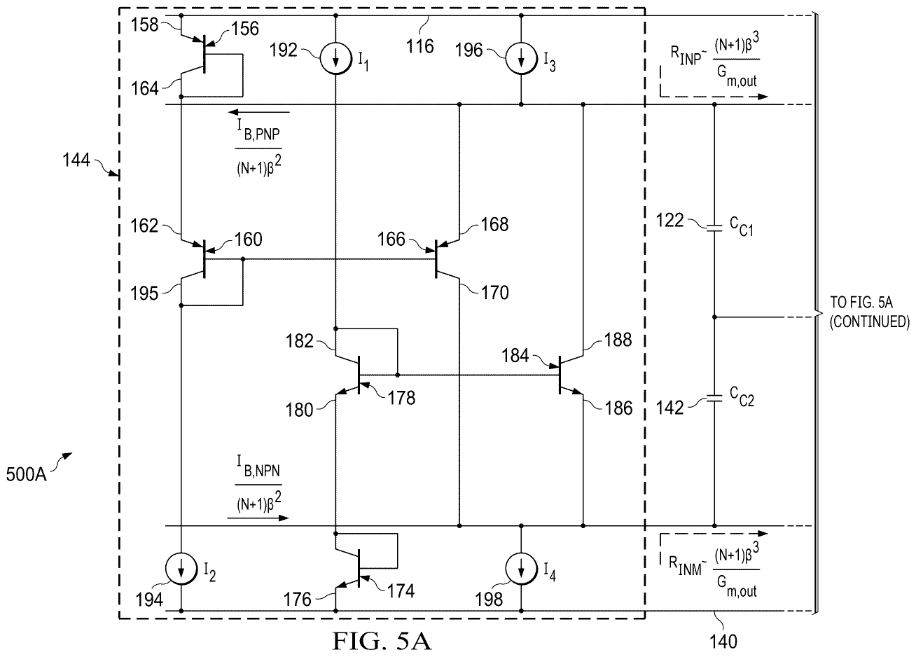

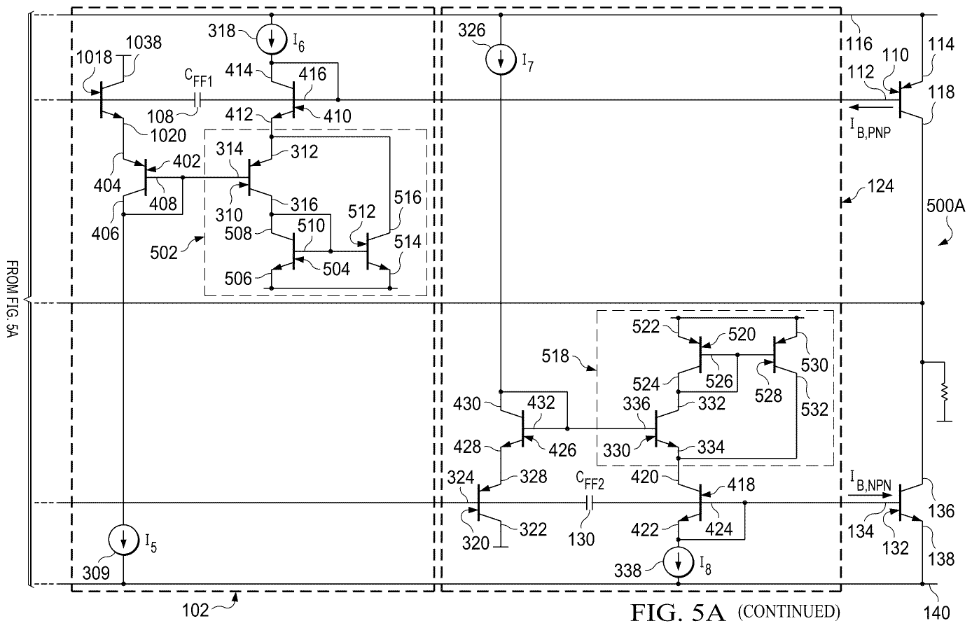

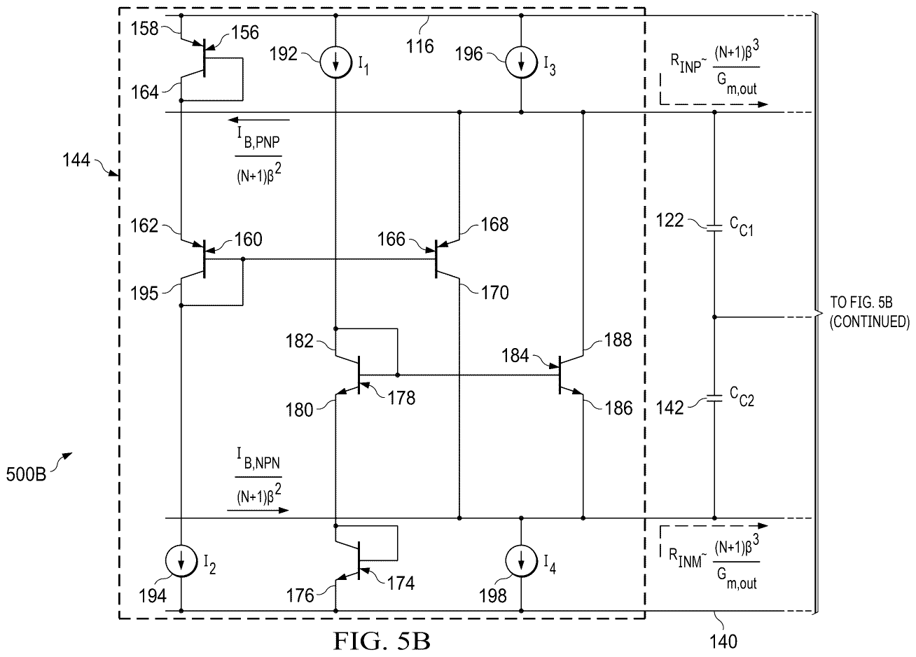

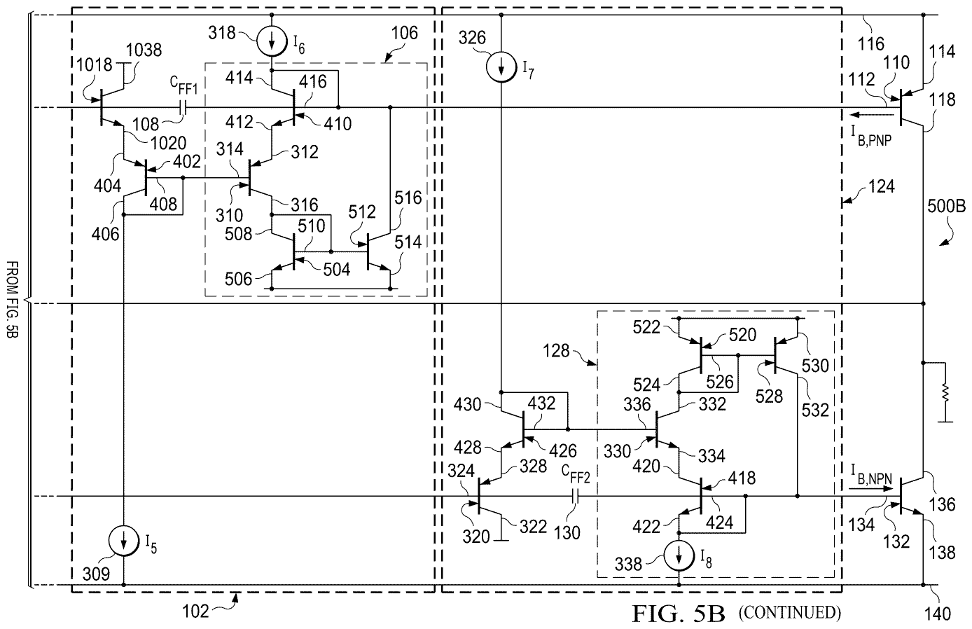

FIG. 5A depicts a schematic diagram of an example of an implementation of the first zero-offset voltage buffer 102 and the second zero-offset voltage buffer 124 of FIG. 4 with additional drive-boosting current loops. As shown in FIG. 5A, the first zero-offset voltage buffer 102 further includes a first drive-boosting current mirror loop 502 comprising an eleventh NPN transistor 504 having an emitter 506 coupled to the second supply terminal 140, a collector 508 coupled to the collector 316 of the fifth PNP transistor 310, where the eleventh NPN transistor 504 is diode-connected. The first drive-boosting current mirror loop 502 further includes a twelfth NPN transistor 512 having an emitter 514 coupled to the second supply terminal 140, a collector 516 coupled to the emitter 312 of the fifth PNP transistor 310, and a base 510 coupled to a base of the eleventh NPN transistor 504. In one example, the second zero-offset voltage buffer 124 further includes a second drive-boosting current mirror loop 518 comprising an eleventh PNP transistor 520 having an emitter 522 coupled to the first supply terminal 116, a collector 524 coupled to the collector 332 of the sixth NPN transistor 330, where the eleventh PNP transistor 520 is diode-connected. The second drive-boosting current mirror loop 518 further includes a twelfth PNP transistor 528 having an emitter 530 coupled to the first supply terminal 116, a collector 532 coupled to the emitter 334 of the sixth NPN transistor 330, and a base 526 coupled to a base of the eleventh PNP transistor 520.

The two drive-boosting current mirror loops described above improve output current drive of the electronic circuit 100 and reduce overdrive recovery time in the electronic circuit 100 with large output transistors 110 and 132. In one example, each of the first drive-boosting current mirror loop 502 and second drive-boosting current mirror loop 518 is configurable to provide 1:N boosting by setting the ratio between the eleventh NPN transistor 504 and the twelfth NPN transistor 512, and the ratio between the eleventh PNP transistor 520 and the twelfth PNP transistor 528, respectively. As a result, the current drive of the zero-offset voltage buffers/drivers are improved by factor of N, while the base currents I_{B,PNP} and I_{B,NPN} from the input stage 1002 are further attenuated by a factor of N+1 in addition to the two stages of current gain (β²), presenting an even higher input impedance to the previous (input) stage 1002.

FIG. 5B depicts a schematic diagram of an example of another implementation of the first zero-offset voltage buffer 102 and the second zero-offset voltage buffer 124 of FIG. 4 with additional drive-boosting current loops. Compared to the implementation of FIG. 5A, the twelfth NPN transistor 512 in the first drive-boosting current mirror loop 502 of the first zero-offset voltage buffer 102 has its collector 516 coupled to the second current terminal 106 of the first zero-offset voltage buffer 102 instead of to the emitter 312 of the fifth PNP transistor 310. In one example, the twelfth PNP transistor 528 in the second drive-boosting current mirror loop 518 of the second zero-offset voltage buffer 124 has its collector 532 coupled to the second current terminal 128 of the second zero-offset voltage buffer 124 instead of to the emitter 334 of the sixth NPN transistor 330.

Example embodiments of the present disclosure are summarized here. Other embodiments can also be understood from the entirety of the specification and the claims filed herein.

Example 1. An electronic circuit including: a first supply terminal; a second supply terminal; first and second input terminals configured to receive an input signal; an output terminal configured to provide an output signal based on the input signal; a first transistor having a first current path terminal coupled to the first supply terminal, a second current path terminal coupled to the output terminal, and a control terminal; a second transistor having a first current path terminal coupled to the output terminal, a second current path terminal coupled to the second supply terminal, and a control terminal; a first voltage buffer having an input coupled to the first input terminal, and an output coupled to the control terminal of the first transistor; a first capacitor coupled between an input of the first voltage buffer and the output of the first voltage buffer; a second voltage buffer having an input coupled to the second input terminal, and an output terminal coupled to the control terminal of the second transistor; a second capacitor coupled between the input of the second voltage buffer and the output of the second voltage buffer; a third capacitor coupled between the input of the first voltage buffer and the output terminal; a fourth capacitor coupled between the input of the second voltage buffer and the output terminal; and a bias circuit configured to provide a first bias current to the first input terminal, and a second bias current to the second input terminal.

Example 2. The electronic circuit of example 1, where the first transistor is a PNP bipolar transistor, and the second transistor is an NPN bipolar transistor.

Example 3. The electronic circuit of one of examples 1 or 2, further including a coin cell battery coupled between the first and second supply terminals.

Example 4. The electronic circuit of one of examples 1 to 3, further including a power amplifier having an input coupled to the output terminal.

Example 5. The electronic circuit of one of examples 1 to 4, further including an analog to a digital converter (ADC) having an input coupled to the output terminal.

Example 6. The electronic circuit of one of examples 1 to 5, where the bias circuit includes: a first current mirror having a first terminal coupled to the first input terminal and a second terminal coupled to the second input terminal, where the first current mirror includes p-type transistors; and a second current mirror having a first terminal coupled to the first input terminal and a second terminal coupled to the second input terminal, where the second current mirror includes n-type transistors.

Example 7. The electronic circuit of one of examples 1 to 6, where: the first current mirror includes: a first p-type transistor having a first current path terminal coupled to a second current path terminal of a third transistor, a second current path terminal coupled to a second current source, where the first p-type transistor is diode-connected; a second p-type transistor having a first current path terminal coupled to the first terminal, a second current path terminal coupled to the second terminal, and where the control terminals of the first p-type transistor and the second p-type transistor are connected; and the second current mirror includes: a first n-type transistor having a first current path terminal coupled to a first current source, a second current terminal coupled to a first current terminal of a fourth transistor, where the first p-type transistor is diode-connected; and a second n-type transistor having a first current path terminal coupled to the first input terminal, a second current path terminal coupled to the second terminal, and where the control terminals of the first n-type transistor and the second n-type transistor are connected.

Example 8. The electronic circuit of one of examples 1 to 7, where the bias circuit further includes: the third transistor having a first current path terminal coupled to the first supply terminal, where the third transistor is a diode-connected p-type transistor; the fourth transistor having a first current path terminal coupled to the second supply terminal, where the fourth transistor is diode-connected n-type transistor; the first current source coupled between the first supply terminal and the first current path terminal of the first n-type transistor of the second current mirror; the second current source coupled between the second current path terminal of the first p-type transistor of the first current mirror and the second supply terminal; a third current source coupled between the first supply terminal and the first input terminal; and a fourth current source coupled between the second input terminal and the second supply terminal.

Example 9. The electronic circuit of one of examples 1 to 8, further including an input stage having first and second outputs respectively coupled to the first and second input terminals, where the first and second outputs of the input stage are differential outputs.

Example 10. The electronic circuit of one of examples 1 to 9, where the input stage includes: a first current mirror having a first terminal coupled to the first input terminal; a third transistor having a first current path terminal coupled to a second terminal of the first current mirror; a fourth transistor having a first current path terminal coupled to the second input terminal, and a control terminal coupled to a control terminal of the third transistor; a first resistor coupled to a second current path terminal of the third transistor; and a second resistor coupled to a second current path terminal of the fourth transistor.

Example 11. The electronic circuit of one of examples 1 to 10, where the input stage further includes: a transconductance amplifier having a first output coupled to the second current path terminal of the third transistor, and a second output coupled to the second current path terminal of the fourth transistor.

Example 12. The electronic circuit of one of examples 1 to 11, further including an antenna coupled to an input of the input stage.

Example 13. The electronic circuit of one of examples 1 to 12, where: the first voltage buffer includes: a third transistor having a control terminal coupled to the first input terminal; and a fourth transistor having a current path terminal coupled to the control terminal of the first transistor, and a control terminal coupled to a first current path terminal of the third transistor; and the second voltage buffer includes: a fifth transistor having a control terminal coupled to the second input terminal; and a sixth transistor having a current path terminal coupled to the control terminal of the second transistor, and a control terminal coupled to a first current path terminal of the fifth transistor.

Example 14. The electronic circuit of one of examples 1 to 13, where: the first voltage buffer includes: a third transistor having a control terminal coupled to the first input terminal; a fourth transistor having a control terminal coupled to the control terminal of the first transistor; a fifth transistor having a current path coupled to a current path of the third transistor; and a sixth transistor having a current path coupled to a current path of the fourth transistor, and a control terminal coupled to a control terminal of the fifth transistor; and the second voltage buffer includes: a seventh transistor having a control terminal coupled to the second input terminal; an eighths transistor having a control terminal coupled to the control terminal of the second transistor; a ninth transistor having a current path coupled to a current path of the seventh transistor; and a tenth transistor having a current path coupled to a current path of the eighths transistor, and a control terminal coupled to a control terminal of the ninth transistor.

Example 15. The electronic circuit of one of examples 1 to 14, where: the first voltage buffer includes: an eleventh transistor having a current path coupled to the current path of the sixth transistor; and a twelfth transistor having a control terminal coupled a control terminal of the eleventh transistor, and a current path coupled to the current path of the fourth transistor; and the second voltage buffer includes: an thirteenth transistor having a current path coupled to the current path of the tenth transistor; and a fourteenth transistor having a control terminal coupled a control terminal of the thirteenth transistor, and a current path coupled to the current path of the eighth transistor.

Example 16. An electronic circuit including: a first supply terminal; a second supply terminal; first and second input terminals each configured to receive an input signal; an output terminal configured to provide an output signal based on the input signal; a first transistor having a first current path terminal coupled to the first supply terminal, a second current path terminal coupled to the output terminal, and a control terminal; a second transistor having a first current path terminal coupled to the output terminal, a second current path terminal coupled to the second supply terminal, and a control terminal; a first voltage buffer includes: a third transistor having a control terminal coupled to the first input terminal; and a fourth transistor having a first current path terminal coupled to the control terminal of the first transistor, and a control terminal coupled to a second current path terminal of the third transistor; a second voltage buffer includes: a fifth transistor having a control terminal coupled to the second input terminal; and a sixth transistor having a current path terminal coupled to the control terminal of the second transistor, and a control terminal coupled to a first current path terminal of the fifth transistor; a first capacitor coupled between the first input terminal and the control terminal of the first transistor; a second capacitor coupled between the second input terminal and the control terminal of the second transistor; a third capacitor coupled between the first input terminal and the output terminal; a fourth capacitor coupled between the second input terminal and the output terminal.

Example 17. The electronic circuit of example 16, where the first transistor is a PNP bipolar transistor, and the second transistor is an NPN bipolar transistor.

Example 18. The electronic circuit of one of examples 16 or 17, further including: a bias circuit having a first current mirror having a first terminal coupled to the first input terminal and a second terminal coupled to the second input terminal, where the first current mirror includes: a first p-type transistor, where the first p-type transistor is diode-connected; a second p-type transistor having a first current path terminal coupled to the first terminal, a second current path terminal coupled to the second terminal; and a second current mirror having a first terminal coupled to the first input terminal and a second terminal coupled to the second input terminal, where the second current mirror includes: a first n-type transistor, where the first p-type transistor is diode-connected; a second n-type transistor having a first current path terminal coupled to the first input terminal, a second current path terminal coupled to the second terminal.

Example 19. The electronic circuit of one of examples 16 to 18, where; the first current mirror further includes: a seventh transistor having a control terminal coupled to a control terminal of the second p-type transistor, where the seventh transistor is diode-connected; an eighth transistor having a control terminal coupled to a first current path terminal of the seventh transistor, a second current path terminal coupled to the control terminal of the first p-type transistor, where the eighth NPN transistor is diode-connected; the second current mirror includes: a ninth transistor having a control terminal coupled to the control terminal of the second n-type transistor, where the ninth transistor is diode-connected; a tenth transistor having a control terminal coupled to a second current path terminal of the ninth transistor, a first current path terminal coupled to a control terminal of the first n-type transistor, where the tenth transistor is diode-connected.

Example 20. The electronic circuit of one of examples 16 to 19, where: the first voltage buffer further includes: a seventh transistor having a first current path terminal coupled to the second current path terminal of the third transistor, and a control terminal coupled to the control terminal of the fourth transistor, where the seventh transistor is diode-connected; an eighth transistor having a first current path terminal coupled to the first current path terminal of the fourth transistor, and a control terminal coupled to the control terminal of the first transistor, where the eighth transistor is diode-connected; and the second voltage buffer further includes a ninth transistor having a first current path terminal coupled to the second current path terminal of the sixth transistor, and a control terminal coupled to to the control terminal of the second transistor, where the tenth PNP transistor is diode-connected; and a tenth transistor having a first current path terminal coupled to the first current path terminal of the fifth transistor, and a control terminal coupled to the control terminal of the sixth transistor, where the tenth transistor is diode-connected.

Example 21. The electronic circuit of one of examples 16 to 20, where: the first buffer further includes a first drive-boosting current mirror loop including: an eleventh transistor having a first current path terminal coupled to the second current path terminal of the fourth transistor, where the eleventh transistor is diode-connected; and a twelfth transistor having a first current path terminal coupled to the first current path terminal of the fourth transistor, and a control terminal coupled to a control terminal of the eleventh transistor; and the second voltage buffer further includes a second drive-boosting current mirror loop including: a thirteenth transistor having a first current path terminal coupled to the first current path terminal of the sixth transistor, where the thirteenth transistor is diode-connected; and a fourteenth transistor having a first current path terminal coupled to the second current path terminal of the sixth transistor, and a control terminal coupled to a control terminal of the thirteenth transistor.

Example 22. The electronic circuit of one of examples 16 to 21, where: ratio between the eleventh transistor and the twelfth transistor is 1:N, and ratio between the thirteenth transistor and the fourteenth transistor is 1:N.

Example 23. The electronic circuit of one of examples 16 to 22, where: the first buffer further includes a first drive-boosting current mirror loop including: an eleventh transistor having a first current path terminal coupled to the second current path terminal of the fourth transistor, where the eleventh transistor is diode-connected; and a twelfth transistor having a first current path terminal coupled to the control terminal of the first transistor, and a control terminal coupled to a control terminal of the eleventh transistor; and the second zero-offset voltage buffer further includes a second drive-boosting current mirror loop including: a thirteenth transistor having a first current path terminal coupled to the first current path terminal of the sixth transistor, where the thirteenth transistor is diode-connected; and a fourteenth transistor having a first current path terminal coupled to the control terminal of the second transistor, and a control terminal coupled to a control terminal of the thirteenth transistor.

Example 24. The electronic circuit of one of examples 16 to 23, where a ratio between the eleventh transistor and the twelfth transistor is 1:N, and a ratio between the thirteenth transistor and the fourteenth transistor is 1:N.

In this description, unless otherwise stated, “about,” “approximately” or “substantially” preceding a parameter means being within +/−10 percent of that parameter or, if the parameter is zero, a reasonable range of values around zero.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein may be reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An electronic circuit comprising:
a first supply terminal;
a second supply terminal;
first and second input terminals configured to receive an input signal;
an output terminal configured to provide an output signal based on the input signal;
a first transistor having a first current path terminal coupled to the first supply terminal, a second current path terminal coupled to the output terminal, and a control terminal;
a second transistor having a first current path terminal coupled to the output terminal, a second current path terminal coupled to the second supply terminal, and a control terminal;
a first voltage buffer having an input coupled to the first input terminal, and an output coupled to the control terminal of the first transistor;
a first capacitor coupled between an input of the first voltage buffer and the output of the first voltage buffer;
a second voltage buffer having an input coupled to the second input terminal, and an output terminal coupled to the control terminal of the second transistor;
a second capacitor coupled between the input of the second voltage buffer and the output of the second voltage buffer;
a third capacitor coupled between the input of the first voltage buffer and the output terminal;
a fourth capacitor coupled between the input of the second voltage buffer and the output terminal; and
a bias circuit configured to provide a first bias current to the first input terminal, and a second bias current to the second input terminal.

2. The electronic circuit of claim 1, wherein the first transistor is a PNP bipolar transistor, and the second transistor is an NPN bipolar transistor.

3. The electronic circuit of claim 1, further comprising a coin cell battery coupled between the first and second supply terminals.

4. The electronic circuit of claim 1, further comprising a power amplifier having an input coupled to the output terminal.

5. The electronic circuit of claim 1, further comprising an analog to a digital converter (ADC) having an input coupled to the output terminal.

6. The electronic circuit of claim 1, wherein the bias circuit comprises:
a first current mirror having a first terminal coupled to the first input terminal and a second terminal coupled to the second input terminal, wherein the first current mirror comprises p-type transistors; and
a second current mirror having a first terminal coupled to the first input terminal and a second terminal coupled to the second input terminal, wherein the second current mirror comprises n-type transistors.

7. The electronic circuit of claim 6, wherein:
the first current mirror includes:
a first p-type transistor having a first current path terminal coupled to a second current path terminal of a third transistor, a second current path terminal coupled to a second current source, wherein the first p-type transistor is diode-connected;
a second p-type transistor having a first current path terminal coupled to the first terminal, a second current path terminal coupled to the second terminal, and wherein the control terminals of the first p-type transistor and the second p-type transistor are connected; and
the second current mirror includes:
a first n-type transistor having a first current path terminal coupled to a first current source, a second current terminal coupled to a first current terminal of a fourth transistor, wherein the first p-type transistor is diode-connected; and
a second n-type transistor having a first current path terminal coupled to the first input terminal, a second current path terminal coupled to the second terminal, and wherein the control terminals of the first n-type transistor and the second n-type transistor are connected.

8. The electronic circuit of claim 7, wherein the bias circuit further comprises:
the third transistor having a first current path terminal coupled to the first supply terminal, wherein the third transistor is a diode-connected p-type transistor;
the fourth transistor having a first current path terminal coupled to the second supply terminal, wherein the fourth transistor is diode-connected n-type transistor;
the first current source coupled between the first supply terminal and the first current path terminal of the first n-type transistor of the second current mirror;
the second current source coupled between the second current path terminal of the first p-type transistor of the first current mirror and the second supply terminal;
a third current source coupled between the first supply terminal and the first input terminal; and
a fourth current source coupled between the second input terminal and the second supply terminal.

9. The electronic circuit of claim 1, further comprising an input stage having first and second outputs respectively coupled to the first and second input terminals, wherein the first and second outputs of the input stage are differential outputs.

10. The electronic circuit of claim 9, wherein the input stage comprises:
a first current mirror having a first terminal coupled to the first input terminal;
a third transistor having a first current path terminal coupled to a second terminal of the first current mirror;
a fourth transistor having a first current path terminal coupled to the second input terminal, and a control terminal coupled to a control terminal of the third transistor;
a first resistor coupled to a second current path terminal of the third transistor; and
a second resistor coupled to a second current path terminal of the fourth transistor.

11. The electronic circuit of claim 9, wherein the input stage further comprises:
a transconductance amplifier having a first output coupled to the second current path terminal of the third transistor, and a second output coupled to the second current path terminal of the fourth transistor.

12. The electronic circuit of claim 9, further comprising an antenna coupled to an input of the input stage.

13. The electronic circuit of claim 1, wherein:
the first voltage buffer comprises:
a third transistor having a control terminal coupled to the first input terminal; and
a fourth transistor having a current path terminal coupled to the control terminal of the first transistor, and a control terminal coupled to a first current path terminal of the third transistor; and
the second voltage buffer comprises:
a fifth transistor having a control terminal coupled to the second input terminal; and
a sixth transistor having a current path terminal coupled to the control terminal of the second transistor, and a control terminal coupled to a first current path terminal of the fifth transistor.

14. The electronic circuit of claim 1, wherein:
the first voltage buffer comprises:
a third transistor having a control terminal coupled to the first input terminal;
a fourth transistor having a control terminal coupled to the control terminal of the first transistor;
a fifth transistor having a current path coupled to a current path of the third transistor; and
a sixth transistor having a current path coupled to a current path of the fourth transistor, and a control terminal coupled to a control terminal of the fifth transistor; and
the second voltage buffer comprises:
a seventh transistor having a control terminal coupled to the second input terminal;
an eighths transistor having a control terminal coupled to the control terminal of the second transistor;
a ninth transistor having a current path coupled to a current path of the seventh transistor; and
a tenth transistor having a current path coupled to a current path of the eighths transistor, and a control terminal coupled to a control terminal of the ninth transistor.

15. The electronic circuit of claim 14, wherein:
the first voltage buffer comprises:
an eleventh transistor having a current path coupled to the current path of the sixth transistor; and
a twelfth transistor having a control terminal coupled a control terminal of the eleventh transistor, and a current path coupled to the current path of the fourth transistor; and
the second voltage buffer comprises:
an thirteenth transistor having a current path coupled to the current path of the tenth transistor; and
a fourteenth transistor having a control terminal coupled a control terminal of the thirteenth transistor, and a current path coupled to the current path of the eighth transistor.

16. An electronic circuit comprising:
a first supply terminal;
a second supply terminal;
first and second input terminals each configured to receive an input signal;
an output terminal configured to provide an output signal based on the input signal;
a first transistor having a first current path terminal coupled to the first supply terminal, a second current path terminal coupled to the output terminal, and a control terminal;
a second transistor having a first current path terminal coupled to the output terminal, a second current path terminal coupled to the second supply terminal, and a control terminal;
a first voltage buffer comprises:
a third transistor having a control terminal coupled to the first input terminal; and
a fourth transistor having a first current path terminal coupled to the control terminal of the first transistor, and a control terminal coupled to a second current path terminal of the third transistor;
a second voltage buffer comprises:
a fifth transistor having a control terminal coupled to the second input terminal; and
a sixth transistor having a current path terminal coupled to the control terminal of the second transistor, and a control terminal coupled to a first current path terminal of the fifth transistor;
a first capacitor coupled between the first input terminal and the control terminal of the first transistor;
a second capacitor coupled between the second input terminal and the control terminal of the second transistor;
a third capacitor coupled between the first input terminal and the output terminal;
a fourth capacitor coupled between the second input terminal and the output terminal.

17. The electronic circuit of claim 16, wherein the first transistor is a PNP bipolar transistor, and the second transistor is an NPN bipolar transistor.

18. The electronic circuit of claim 16, further comprising:
a bias circuit having
a first current mirror having a first terminal coupled to the first input terminal and a second terminal coupled to the second input terminal, wherein the first current mirror comprises:
a first p-type transistor, wherein the first p-type transistor is diode-connected;
a second p-type transistor having a first current path terminal coupled to the first terminal, a second current path terminal coupled to the second terminal; and
a second current mirror having a first terminal coupled to the first input terminal and a second terminal coupled to the second input terminal, wherein the second current mirror comprises:
a first n-type transistor, wherein the first p-type transistor is diode-connected;
a second n-type transistor having a first current path terminal coupled to the first input terminal, a second current path terminal coupled to the second terminal.

19. The electronic circuit of claim 18, wherein;
the first current mirror further includes:
a seventh transistor having a control terminal coupled to a control terminal of the second p-type transistor, wherein the seventh transistor is diode-connected;
an eighth transistor having a control terminal coupled to a first current path terminal of the seventh transistor, a second current path terminal coupled to the control terminal of the first p-type transistor, wherein the eighth NPN transistor is diode-connected;
the second current mirror includes:
a ninth transistor having a control terminal coupled to the control terminal of the second n-type transistor, wherein the ninth transistor is diode-connected;
a tenth transistor having a control terminal coupled to a second current path terminal of the ninth transistor, a first current path terminal coupled to a control terminal of the first n-type transistor, wherein the tenth transistor is diode-connected.

20. The electronic circuit of claim 16, wherein:
the first voltage buffer further includes:
a seventh transistor having a first current path terminal coupled to the second current path terminal of the third transistor, and a control terminal coupled to the control terminal of the fourth transistor, wherein the seventh transistor is diode-connected;
an eighth transistor having a first current path terminal coupled to the first current path terminal of the fourth transistor, and a control terminal coupled to the control terminal of the first transistor, wherein the eighth transistor is diode-connected; and
the second voltage buffer further includes
a ninth transistor having a first current path terminal coupled to the second current path terminal of the sixth transistor, and a control terminal coupled to to the control terminal of the second transistor, wherein the tenth PNP transistor is diode-connected; and
a tenth transistor having a first current path terminal coupled to the first current path terminal of the fifth transistor, and a control terminal coupled to the control terminal of the sixth transistor, wherein the tenth transistor is diode-connected.

21. The electronic circuit of claim 20, wherein:
the first buffer further includes a first drive-boosting current mirror loop comprising:
an eleventh transistor having a first current path terminal coupled to the second current path terminal of the fourth transistor, wherein the eleventh transistor is diode-connected; and
a twelfth transistor having a first current path terminal coupled to the first current path terminal of the fourth transistor, and a control terminal coupled to a control terminal of the eleventh transistor; and
the second voltage buffer further includes a second drive-boosting current mirror loop comprising:
a thirteenth transistor having a first current path terminal coupled to the first current path terminal of the sixth transistor, wherein the thirteenth transistor is diode-connected; and
a fourteenth transistor having a first current path terminal coupled to the second current path terminal of the sixth transistor, and a control terminal coupled to a control terminal of the thirteenth transistor.

22. The electronic circuit of claim 21, wherein:
ratio between the eleventh transistor and the twelfth transistor is 1:N, and ratio between the thirteenth transistor and the fourteenth transistor is 1:N.

23. The electronic circuit of claim 20, wherein:
the first buffer further includes a first drive-boosting current mirror loop comprising:
an eleventh transistor having a first current path terminal coupled to the second current path terminal of the fourth transistor, wherein the eleventh transistor is diode-connected; and
a twelfth transistor having a first current path terminal coupled to the control terminal of the first transistor, and a control terminal coupled to a control terminal of the eleventh transistor; and
the second zero-offset voltage buffer further includes a second drive-boosting current mirror loop comprising:
a thirteenth transistor having a first current path terminal coupled to the first current path terminal of the sixth transistor, wherein the thirteenth transistor is diode-connected; and
a fourteenth transistor having a first current path terminal coupled to the control terminal of the second transistor, and a control terminal coupled to a control terminal of the thirteenth transistor.

24. The electronic circuit of claim 23, wherein a ratio between the eleventh transistor and the twelfth transistor is 1:N, and a ratio between the thirteenth transistor and the fourteenth transistor is 1:N.
